(19) United States
(12) Patent Application Publication
(10) Pub. No.: US 2013/0329390 A1
(43) Pub. Date: Dec. 12, 2013

(54) SEMICONDUCTOR DEVICES

(71) Applicant: SAMSUNG ELECTRONICS CO., LTD., Suwon-Si (KR)

(72) Inventors: Onpil SHIN, Hwaseong-si (KR); Minho SEO, Seoul (KR)

(73) Assignee: Samsung Electronics Co., Ltd., Suwon-Si (KR)

(21) Appl. No.: 13/785,137

(22) Filed: Mar. 5, 2013

(30) Foreign Application Priority Data
Jun. 12, 2012 (KR) 10-2012-0062809

(51) Int. Cl. H05K 1/02

(52) U.S. Cl. CPC H05K 1/025
USPC 361/783

(57) ABSTRACT

A semiconductor device includes a package board having a front side and a back side opposite to each other. A first memory device has data pins and is mounted on the front side of the package board, and a second memory device has data pins and is mounted on the back side of the package board. The data pins of the first and second memory devices have a same arrangement. A controller provides data signals to the first and second memory devices, with the same data signal provided from the controller to one data pin of the first memory device and one data pin of the second memory device.

### CROSS-REFERENCE TO RELATED APPLICATIONS

This U.S. non-provisional patent application claims priority under 35 U.S.C. §119 to Korean Patent Application No. 10-2012-0062809, filed on Jun. 12, 2012, the entirety of which is incorporated by reference herein.

### BACKGROUND

1. Field

One or more embodiments described herein relate to a semiconductor device.

2. Background

Most electronic devices are equipped with at least one semiconductor memory and a processor. While efforts have been made to improve both, differences in operational speeds of the memory and processor continue to limit performance. For example, in many cases, the operational speed of the memory is slower than the processor. As a result, applications and other functions can only be executed within the constraints of the memory.

In order to reduce power consumption, additional efforts have been made to reduce the operational voltages of electronic devices. However, reducing the operational voltage of a device may have an adverse effect on signal integrity, for example, as a result of impedance mismatching of signal transfers.

### SUMMARY

In accordance with one embodiment, a semiconductor device includes a first memory device having data pins; a second memory device having data pins of the same arrangement as the data pins of the first memory device; a controller transmitting data signals to the first and second memory devices; and data lines connected between the controller and the first and second memory devices to transmit the data signals to the first and second memory devices in a swap manner.

In accordance with another embodiment, a semiconductor device includes a package board having a front side and a back side opposite to each other; a first memory device mounted on the front side of the package board and having data pins; a second memory device mounted on the back side of the package board and having data pins of the same arrangement as the data pins of the first memory device; and a controller providing data signals in common to the first and second memory devices. The same data signal may be provided to one data pin of the first memory device and one data pin of the second memory device from the controller. A distance between the one data pin of the first memory device and the one data pin of the second memory device may be shorter than distances between the one data pin of the first memory device and the rest data pins except the one data pin of the second memory device.

In accordance with another embodiment, an apparatus includes a board, a first memory device having a plurality of data pins, a second memory device having a plurality of data pins, and signal lines coupling the data pins of the first memory device to the data pins of the second memory device. The first and second memory devices are coupled to opposing sides of the board in an overlapping relationship, and same data carried by one signal line is input into a first data pin of the first memory device and a first data pin of the second memory device. The first data pin of the first memory device and the first data pin of the second memory device arranged at different pin positions.

The first and second memory devices may be enabled by different chip select signals, and the first pin of the first memory device and the first pin of the second memory device have different pin addresses.

The first data pin of the first memory device and the first data pin of the second memory device are separated by a first distance, and the first data pin of the first memory device and remaining ones of the data pins of the second memory device may be separated by distances greater than the first distance. Also, a center of the first memory device is offset from a center of the second memory device. Also, the signal lines may be located within an interior of the board or may be coupled to a surface of the board.

The apparatus further includes a controller coupled the signal lines and the board. The controller may generate or have an on-die-termination (ODT) circuit and generation of an ODT signal is disabled when the same data is carried by the one signal line for input into the first data pin of the first memory device and the first data pin of the second memory device. Also, the controller may be coupled to the board at a location that does not overlap the first memory device or the second memory device.

In accordance with another embodiment, an apparatus includes a first memory device having a plurality of data pins, a second memory device having a plurality of data pins, and signal lines coupling the data pins of the first memory device to the data pins of the second memory device. The data pins of the first memory device having a same arrangement as the data pins of the second memory device, and same data carried by one signal line input into a first data pin of the first memory device and a first data pin of the second memory device. The first data pin of the first memory device and the first data pin of the second memory device having different pin addresses.

The apparatus further includes a board, wherein the first and second memory devices are coupled to opposing sides of the board in an overlapping relationship. Also, the first data pin of the first memory device and the first data pin of the second memory device are separated by a first distance, and the first data pin of the first memory device and remaining ones of the data pins of the second memory device are separated by distances greater than the first distance. A center of the first memory device is offset from a center of the second memory device.

The first and second memory devices are enabled by different chip select signals. And, the first pin of the first memory device and the first pin of the second memory device are at different pin positions. The signal lines may be located within an interior of the board.

In accordance with another embodiment, an apparatus includes a controller, a circuit configured to generate on-die-termination (ODT) signal, a first memory device having a plurality of data pins, a second memory device having a plurality of data pins, and a plurality of signal lines coupled between the controller and the first and second memories. The circuit is disabled when same data is carried by one signal line for input into a first data pin of the first memory device and a first data pin of the second memory device. The circuit may be located in the controller or on a board that includes the controller and memories.

The first and second memory devices are coupled to opposing sides of the board in an overlapping relationship, and the first data pin of the first memory device and the first data pin of the second memory device are arranged at different pin positions. Also, the first data pin of the first memory device and the first data pin of the second memory device are separated by a first distance, and the first data pin of the first memory device and remaining ones of the data pins of the second memory device are separated by distances greater than the first distance.

The first and second memory devices are enabled by different chip select signals, and the first pin of the first memory device and the first pin of the second memory device have different pin addresses. The signal lines may be located within an interior of the board or on a surface of the board.

### BRIEF DESCRIPTION OF THE DRAWINGS

FIG. 1 shows one embodiment of a semiconductor device.

FIG. 2 shows one example of how a controller may be connected to multiple memory devices in the semiconductor device of FIG. 1.

FIG. 3 shows another example of how a controller may be connected to multiple memory devices in the semiconductor device of FIG. 1.

FIGS. 4A, 4B, 5A, and 5B show one way in which a swap may be performed between data pins of a controller and data pins of memory devices in a semiconductor device.

FIG. 6 shows another embodiment of a semiconductor device.

FIG. 7 shows a plan view of one embodiment of a semiconductor device.

FIG. 8 shows an electronic device that includes any of the aforementioned embodiments of the semiconductor device.

FIG. 9 shows another electronic device including any of the aforementioned embodiments of the semiconductor device.

### DETAILED DESCRIPTION

The inventive concept will now be described more filly hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

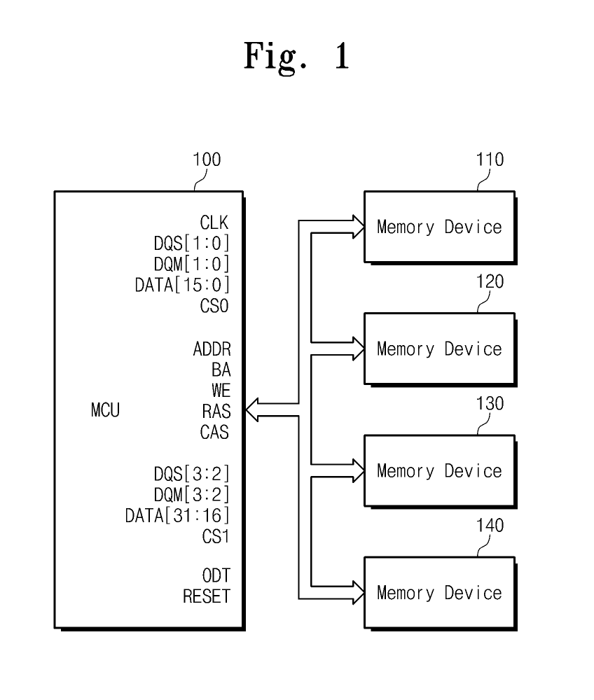

FIG. 1 shows one embodiment of a semiconductor device which includes a controller 100 and a plurality of memory devices 110, 120, 130, and 140. In some cases, controller 100 and memory devices 110, 120, 130, and 140 may be individually packaged semiconductor chips. In other embodiments, the controller and memory devices may be implemented on a same chip or package or different memory devices may be included on different chips or in different packages.

Also, memory devices 110, 120, 130, and 140 may have the same operational properties or the memory devices may have different properties. Also, the memory devices 110, 120, 130, and 140 may have input/output pins arranged according to a standard such as Joint Electron Device Engineering Council (JEDEC). For example, each memory device may be a DDR2 DRAM, DDR3 DRAM, mobile DRAM, EDP, PRAM, OneDRAM, Pseudo SRAM, LpDDR-based DRAM, FRAM, Graphic DRAM, or ReRAM.

In other embodiments, each memory device may be a NAND flash, NOR flash, OneNAND, PRAM, or ReRAM. In other embodiments, the memory devices may be DDR2 DRAMs or DDR3 DRAMs and one controller 100. In other embodiments, only one memory device may be included with the controller.

The controller 100 controls data input/output of the memory device(s) and may be connected to the memory devices through one or more bus channels. Each bus channel may transmit a control signal and a data signal to all or respective ones of memory devices 110, 120, 130, and 140. In one embodiment, controller 110 may transmit/receive 32-bit data signals through one bus channel.

As shown in FIG. 1, the controller may have a number of pins. For example, controller 100 may include a first data pin group connected to a first bus line B0 transmitting first byte-data signals DATA[7:0], a second data pin group connected to a second bus line B1 transmitting second byte-data signals DATA[15:8], a third data pin group connected to a third bus line B2 transmitting third byte-data signals DATA[23:16], and a fourth data pin group connected to a fourth bus line B3 transmitting fourth byte-data signals DATA[31:24].

The controller 100 may also include first strobe pins connected to a first strobe line SL0 transmitting first data strobe signals DQS[1:0] and second strobe pins connected to a second strobe line SL1 transmitting second data strobe signals DQS[3:2].

The controller 100 may also include first mask pins connected to a first mask line ML0 transmitting first data mask signals DQM[1:0] and second mask pins connected to a second mask line ML1 transmitting second data mask signals DQM[3:2].

The controller 100 may also include a first chip selection pin connected to a first chip selection line CSL0 transmitting a first chip selection signal CS0 and a second chip selection pin connected to a second chip selection line CSL1 transmitting a second chip selection signal CS1.

The controller 100 may also include input/out pins outputting control signals BA, WE, RAS, and CAS, an address signal ADDR, an on-die-termination signal ODT, and a reset signal RESET.

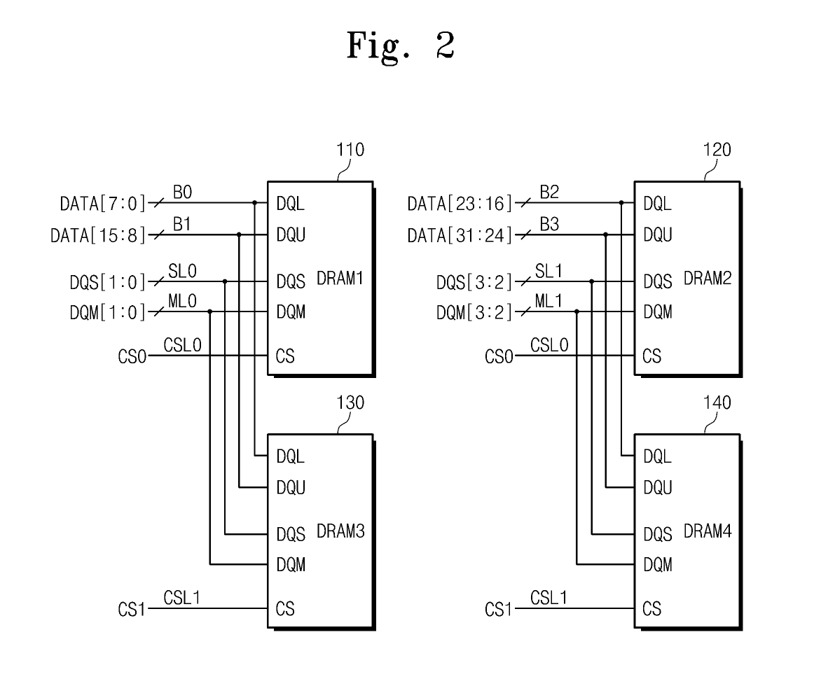

FIG. 2 shows one way the pins of the controller may be coupled to the memory devices. The controller may be directly coupled to the memory devices through interconnections to these pins or, for example, additional logic may be included between the controller and one or more of the memories to facilitate communication therebetween.

According to the present example, the first and second data pin groups of the controller 100 may be connected to first and third memory devices 110 and 130 through first and second bus lines B0 and B1. The third and fourth data pin groups of the controller 100 may be connected to the second and fourth memory devices 120 and 140 through third and fourth bus lines B2 and B3.

The first chip selection pin of the controller 100 may be connected to first and second memory devices 110 and 120 through first chip selection line CSL0. The second chip selection pin of the controller 100 may be connected to third and fourth memory devices 130 and 140 through second chip selection line CSL1. As a result, controller 100 may select a first pair of memory devices 110 and 120 or a second pair of memory devices 130 and 140 for collectively storing Data [31:0]. In one embodiment, both pairs may be simultaneously selected, for example, to effect a redundant data backup operation.

More specifically, the first byte-data signals DATA[7:0] may be input into low data pin groups DQL of the first and third memory devices 110 and 130 through first bus line B0. The second byte-data signals DATA[15:8] may be input into upper data pin groups DQU of the first and third memory devices 110 and 130 through second bus line B1. The third byte-data signals DATA[23:16] may be input into low data pin groups DQL of the second and fourth memory devices 120 and 140 through third bus line B2. And, the fourth byte-data signals DATA[31:24] may be input into upper data pin groups DQU of the second and fourth memory devices 120 and 140 through fourth bus line B3.

The first data strobe signals DQS[1:0] may be input into data strobe pines DQS of the first and third memory devices 110 and 130 through first strobe line SL0, and the second data strobe signals DQS[3:2] may be input into data strobe pines DQS of the second and fourth memory devices 120 and 130 through second strobe line SL1.

The first data mask signals DQM[1:0] may be input into the data mask pins DQM of the first and third memory devices 110 and 130 through first mask line ML0, and the second data mask signals DQM[3:2] may be input into data mask pins DQM of the second and fourth memory devices 120 and 140 through second mask line ML1.

The first chip selection signal CS0 may be input into chip selection pins CS of the first and second memory devices 110 and 120 through first chip selection line CSL0, and the second chip selection signal CS1 may be input into chip selection pines CS of the third and fourth memory devices 130 and 140 through second chip selection line CSL1. In other words, the first and second memory devices 110 and 120 may be accessed by the first chip selection signal CS0, and the third and fourth memory devices 130 and 140 may be accessed by the second chip selection signal CS1.

In one embodiment, a swap operation may be performed with respect to input of the first and second byte-data signals DATA[7:0] and DATA[15:8] into first and third memory devices 110 and 130. This may be accomplished based on a difference between the pin-addresses of the first memory device 110 into which the first and second byte-data signals DATA[7:0] and DATA[15:8] are input and the pin-addresses of the third memory device 130 into which the first and second byte-data signals DATA[7:0] and DATA[15:8] are input. Additionally, or alternatively, a swap operation may be performed for the third and fourth byte-data signals DATA[23:16] and DATA[31:24] relative to the second and fourth memory devices 120 and 140.

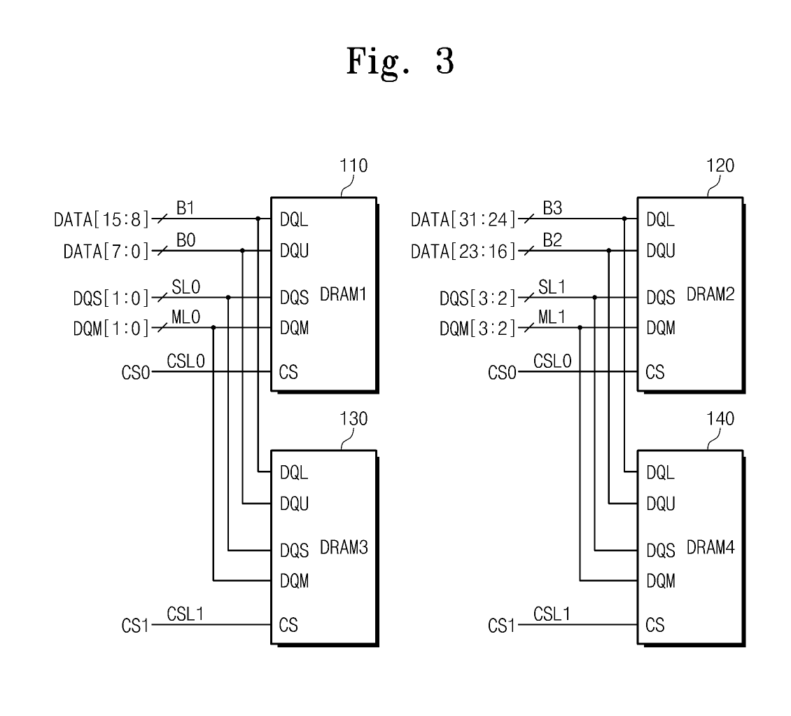

FIG. 3 shows another one way the pins of the controller may be coupled to the memory devices. In this embodiment, bus lines B0 to B3 for carrying byte units may be respectively connected to data pin groups DQU and DQL of memory devices 110, 120, 130, and 140 in a swap manner. In other words, the first byte-data signals DATA[7:0] may be input into the upper data pin groups DQU of the first and third memory devices 110 and 130 through first bus line B0. The second byte-data signals DATA[15:8] may be input into the low data pin groups DQL of the first and third memory devices 110 and 130 through second bus line B1. The third byte-data signals DATA[23:16] may be input into the upper data pin groups DQU of the second and fourth memory devices 120 and 140 through third bus line B2. And, the fourth byte-data signals DATA[31:24] may be input into the low data pin groups DQL of second and fourth memory devices 120 and 140 through fourth bus line B3.

The swap operation in FIG. 3 is performed in units of bytes. In other embodiments, swap operations may be performed in units of bits for pin groups DQL and DQU in the swap manner by units of bits.

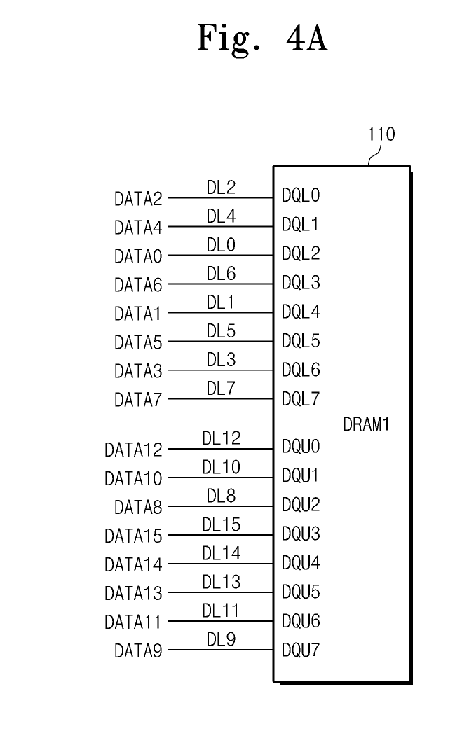

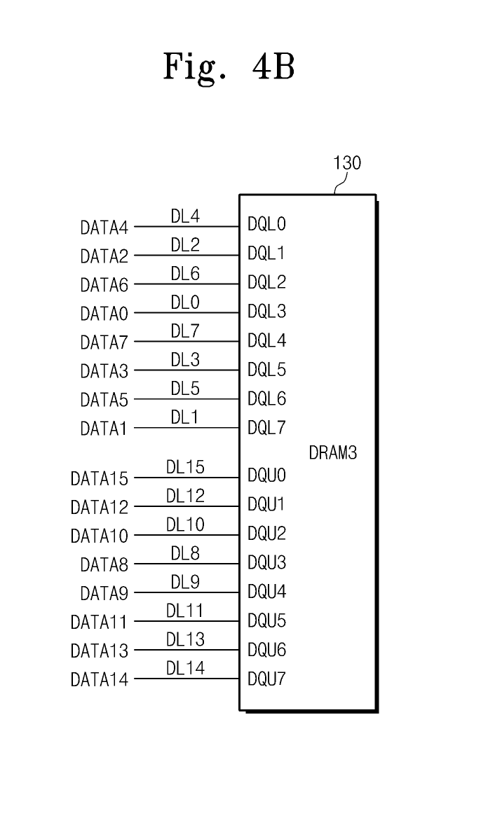

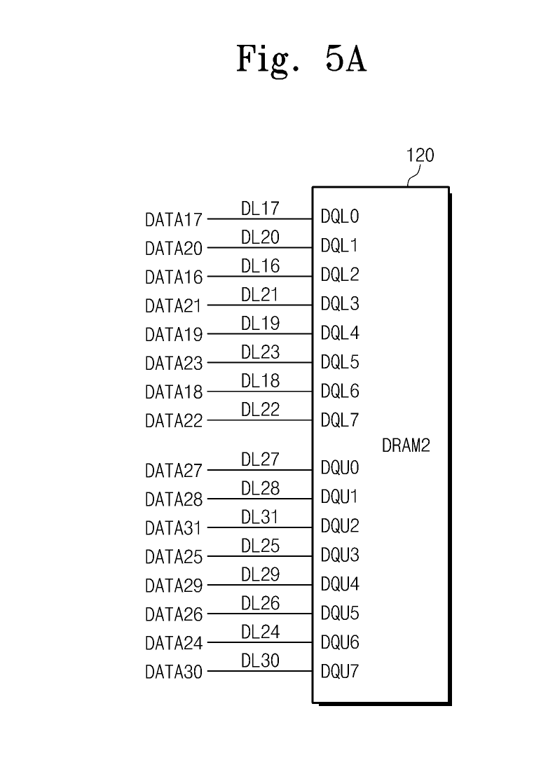

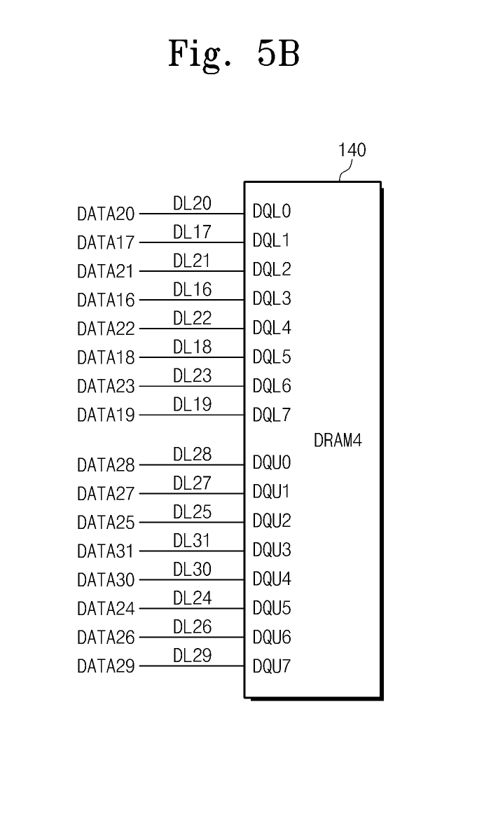

FIGS. 4A, 4B, 5A, and 5B correspond to embodiments in which swap operations are performed between data pins of a controller and data pins of memory devices in units of bits. In these embodiments, the first to fourth memory devices 110, 120, 130, and 140 are 16-bit memory devices but the devices may be 32-bit, 64-bit or other types of devices in other embodiments. Each memory device 110, 120, 130, and 140 may include low data pins DQL0 to DQL7 and upper data pins DQU0 to DQU7. The data pins DQL0 to DQL7 and DQU0 to DQU7 of the memory devices may be arranged, for example, in accordance with the JEDEC standard.

The first bus line B0 transmitting the first byte-data signals DATA[7:0] of FIG. 2 may include data lines DL0 to DL7. The first byte-data signals DATA[7:0] may be input into the first and third memory devices in a swapped manner on a bit-by-bit basis.

Referring to FIGS. 4A and 4B, data lines DL2 and DL4 may be respectively connected to data pins DQL0 of the first and third memory devices 110 and 130 having the same data pin arrangement. More specifically, data line DL2 may be connected to data pin DQL0 of first memory device 110 and data line DL4 may be connected to data pin DQL0 of the third memory device 130.

In other words, one data signal outputted from controller 100 may be input into data pins of the first and third memory devices 110 and 130 which have pin-addresses different from each other, respectively. As illustrated in FIGS. 4A and 4B, a first data signal DATA0 output from the controller may be input into data pin DQL2 of the first memory device 110 and data pin DQL3 of third memory device 130 through a same data line, e.g., data line DL0.

Thus, when the first chip selection signal CS0 is enabled, data signal DATA0 may be input into data pin DQL2 of the first memory device 110 through data line DL0. And, when the second chip selection signal CS1 is enabled, data signal DATA0 may be input into data pin DQL3 of the third memory device 130 through data line DL0.

Data lines DL1 to DL7 may also be connected to the first and third memory devices 110 and 130 in a swap manner on a bit-by-bit basis as illustrated in FIGS. 4A and 4B.

Referring now to the upper data pins, the second bus line B1 transmitting the second byte-data signals DATA[15:8] may include data lines DL8 to DL15. Data line DL8 transmitting data signal DATA8 output from the controller may be connected to data pin DQU2 of the first memory device 110 and data pin DQU3 of the third memory device 130. If the first chip selection signal CS0 is enabled, data signal DATA8 may be input into data pin DQU2 of the first memory device 110 through data line DL8. If the second chip selection signal CS1 is enabled, data signal DATA8 may be input into data pin DQU3 of the third memory device 130.

Data lines DL9 to DL15 may be connected to the first and third memory devices 110 and 130 in a swapped manner on a bit-by-bit basis as shown in FIGS. 4A and 4B.

As described above, when data lines DL0 to DL7 and DL8 to DL15 are connected to the data pins of the first and third memory devices 110 and 130 in a swapped mariner on a bit-by-bit basis, data pins input with the same data signal may be adjacent to each other on a printed circuit board (PCB). For example, the third low data pin DQL2 of the first memory device 110 and the fourth low data pin DQL3 of the third memory device, both of which are connected to first data line DL0, may be disposed to be adjacent to each other in a plan view. In other embodiments, the data pins connected to the data line DL0 may be other data pins of the first and third memory devices 110 and 130, which are different from the DQL2 of the first memory device 110 and data pin DQL3 of the third memory device 130.

Referring to FIGS. 5A and 5B, byte-data signals DATA[23:16] and DATA[31:24] may also be connected to the second and fourth memory devices 120 and 140 in a swapped manner on a bit-by-bit basis.

For example, the third bus line B2 transmitting the third byte-data signals DATA[23:16] may include data lines DL16 to DL23. Data line DL16 transmitting data signal DATA16 output from controller 100 may be connected to data pin DQL2 of the second memory devices 120 and data pin DQL3 of the fourth memory device 140. If first chip selection signal CS0 is enabled, data signal DATA16 may be input into the third low data pin DQL2 of the second memory device 120 through data line DL16. If the second chip selection signal CS1 is enabled, data signal DATA16 may be input into data pin DQL3 of the fourth memory device 140.

Bus line B3 transmitting the byte-data signal DATA[31:24] may include data lines DL24 to DL31. These data lines may also be connected to the second and fourth memory devices 120 and 140 in a swapped manner on a bit-by-bit basis as illustrated in FIGS. 5A and 5B.

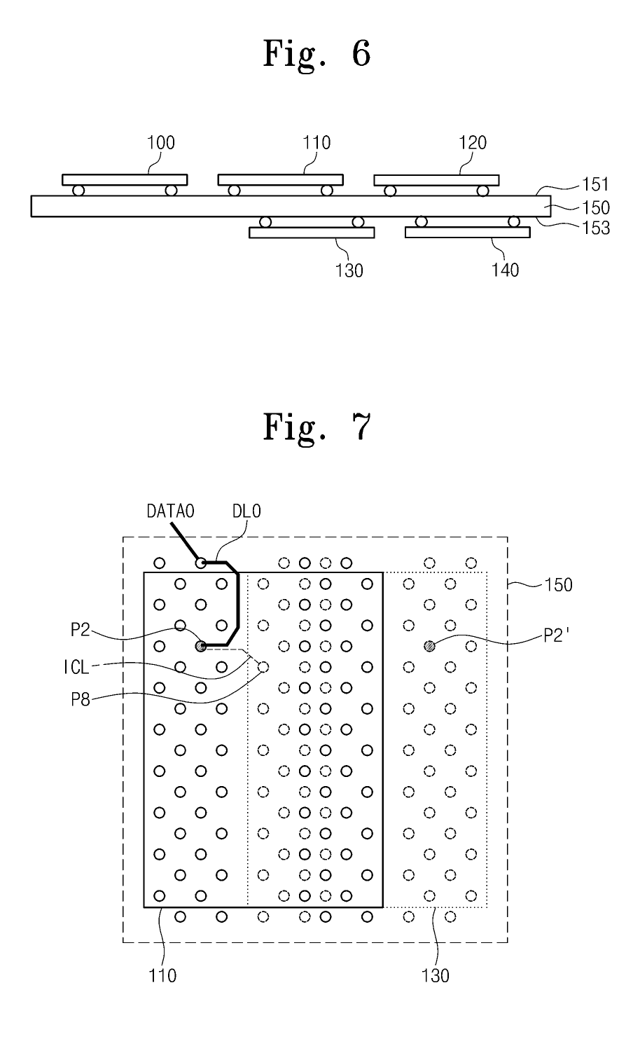

FIG. 6 shows an embodiment of a semiconductor device having an arrangement of memory devices and FIG. 7 shows a plan view this semiconductor device. The semiconductor device includes controller 100 and memory devices 110, 120, 130, and 140 mounted on a package board 150.

The semiconductor device may be mounted to the board using various packaging techniques. For example, the controller and memory devices may be mounted on the package board by a package-on-package (POP) technique, ball grid arrays (BGAs) technique, chip scale packages (CSPs) technique, plastic leaded chip carrier (PLCC) technique, plastic dual in-line package (PDIP) technique, die-in-waffle pack technique, die-in-wafer foul) technique, chip-on-board (COB) technique, ceramic dual in-line package (CERDIP) technique, plastic metric quad flat package (PMQFP) technique, plastic quad flat package (PQFP) technique, small outline package (SOIC) technique, shrink small outline package (SSOP) technique, thin small outline package (TSOP) technique, thin quad flat package (TQFP) technique, system-in-package (SIP) technique, multi-chip package (MCP) technique, wafer-level fabricated package (WFP) technique, or wafer-level processed stack package (WSP) technique.

In some embodiments, the package board 150 may have a front side 151 and a back side 153 opposite to each other. Additionally, the package board may include a plurality of interconnection lines disposed on the front side 151 and/or the back side 153 and inner interconnections may be included within the package board.

In some embodiments, the plurality of memory devices 110, 120, 130, and 140 may be mounted on the front side 151 and back side 153 of the package board 150. For example, the first and second memory devices 110 and 120 may be mounted on the front side 151 of the package board 150, and the third and fourth memory devices 130 and 140 may be mounted on the back side 153 of the package board 150. The controller 110 may be mounted on the front side 151 or the back side 153 of the package board 150. Additionally, centers of the memory devices 110 and 120 mounted on the front side 151 may be vertically offset from centers of the memory devices 130 and 140 mounted on the back side 153.

In some embodiments, if the first to fourth memory devices 110, 120, 130, and 140 have input/output pins of the same arrangement, the third and fourth memory devices 130 and 140 may be rotated by 180 degrees with respect to the first and second memory devices 110 and 120 on the back side 153 of the package board 150.

When the plurality of memory devices 110, 120, 130, and 140 are mounted on the package board 150, positions of the data pins having the same address may be different from each other on the package board 150. More specifically, the first and third memory devices 110 and 130 may be respectively mounted on the front side 151 and 153 of the package board 150 such that the input/output pins (e.g., data pins) of the first memory device 110 may be mirror-symmetric to the input/output pins (i.e., data pins) of the third memory device 130 in a plan view as illustrated in FIG. 7.

As described with reference to FIG. 2, the controller 100 and the first and third memory devices 110 and 130 may be connected to the first and second bus lines B0 and B1, and the controller 100 and the second and fourth memory devices 120 and 140 may be connected to the third and fourth bus lines B2 and B3 of FIG. 2.

If connections between the controller and memory devices are arranged so that one data signal is transmitted to data pins having the same address of the memory devices (e.g., the first data pin of the controller is connected to the first data pins of the first memory devices), then a skew effect may be produced to degrade performance.

More specifically, if positions of the memory devices on a package board are different from each other and have the same pin addresses, a distance between the controller and the first memory device may be substantially different from a distance between the controller and the third memory device. In this case, lengths of the data lines connecting the controller to the first and third memory devices will be substantially different on the package board, especially on a pin-by-pin basis. As a result of this data line length difference, skew in the signals transmitted between the controller and memories may occur.

One way that may be attempted to overcome this problem involves making the lengths of the data lines connecting the controller to the first and third memory devices equal to each other. To achieve this, the lengths of the data lines may be lengthened. However, such an approach may complicate the design and placement of the data lines on the package board. For example, the first and third memory devices may be designed to partially overlap in a plan view, such that data pins having the same address in the first and third memory devices may be spaced apart a significant distance from each other. As a result, it is difficult to connect data lines of the same length to data pins having the same address.

However, in accordance with one embodiment as shown in FIG. 7, when first and third memory devices 110 and 130 are disposed to be mirror-symmetric to or in an overlapping relationship with each other on package board 150, data line DL0 transmitting the data DATA0 may be connected to a first data pin P2 of the first memory device 110. The first data pin P2 of the first memory device 110 may be connected to a second data pin (e.g., P8) of the third memory device 130 through interconnection ICL disposed within the interior of package board 150.

Here, the second data pin P8 of the third memory device 130 may be a data pin disposed at a shortest distance from the first data pin P2 of the first memory device 110 or at a distance which falls within a predetermined distance range. For example, the distance between the first data pin P2 of the first memory device 110 and the second data pin P8 of the second memory device 130 may be shorter than distances between the first data pin P2 of the first memory device 110 and the rest data pins of the third memory device 130.

Thus, the data pins of the first and third memory devices 110 and 130 which have different pin addresses but which receive the same data signal may be adjacent to each other on different sides of the package board 150.

Another consideration relates to signal integrity. When the memory devices are operated at a high frequency (e.g., 400 MHz or more), the integrity of signals transmitted through the data lines may deteriorate, for example, as a result of impedance mismatching. To compensate, one approach involves including on-die-termination (ODT) circuits for the memory devices in an attempt to improve signal integrity. However, when the memory devices and ODT circuits are operated at high speed, resistors for increasing driver strength may be selected and as a result power consumption of the memory devices may increase.

To prevent these effects, in accordance with one embodiment when the data signals are transmitted to multiple ones of memory devices 110, 120, 130, and 140, an ODT signal of the controller 100 is disabled. Thus, the ODT circuits of the memory devices 110, 120, 130, and 140 may not be used and the data signals of the controller 100 may be input into the plurality of memory devices 110, 120, 130, and 140 without increased power consumption.

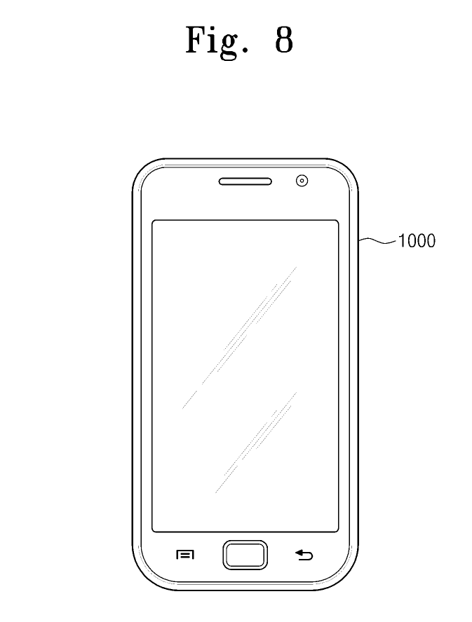

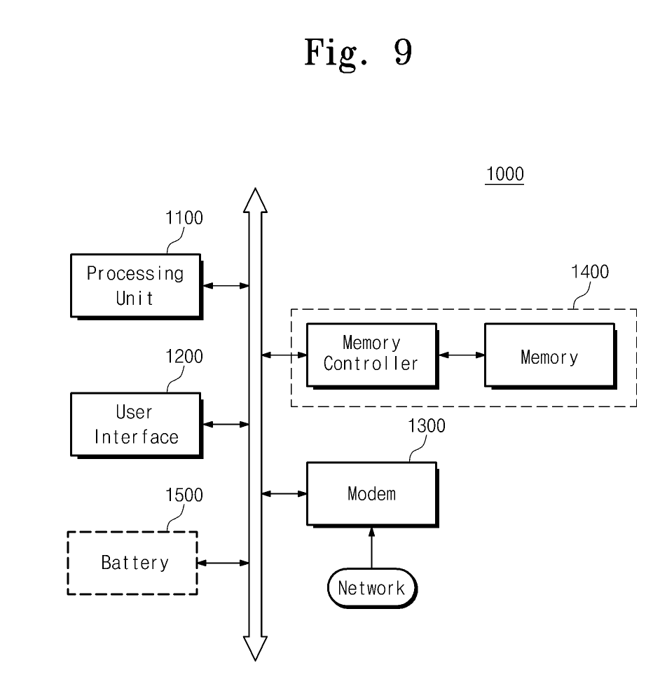

FIG. 8 shows an example of an electronic device that includes one or more of the foregoing embodiments of the semiconductor device, and FIG. 9 shows an example of a block diagram for this device. While the electronic device is shown as a mobile/smart phone 1000 in FIG. 8, in other embodiments the electronic device may be any one of a number of other devices including but not limited to a personal digital assistant (PDA), a portable computer, a web tablet, a wireless phone, a mobile phone, a digital music player, a navigation device, a memory card or other electronic products which, for example, may or may not receive and/or transmit information data by a wireless connection.

Referring to FIG. 9, electronic device 1000 may include a processing unit 1100, a user interface 1200, a MODEM 1300 such as a baseband chipset, and the memory system 1400 which may include the controller and memories in accordance with the previously discussed embodiments. If electronic device 1000 is a mobile device, the electronic device may further include a battery 1550 for supplying an operation voltage. The electronic device may also have an application chipset and/or camera image processor (CIS).

In this device, routing for the memory devices mounted on the package board may be easily performed by the data input/output path swap between the controller and the memory devices without the need to include an additional logic device. As a result, design of the interconnections may be improved. Thus, it is possible to prevent an increase in power consumption caused by the ODT circuits used for improving the signal integrity.

Additionally, the lengths of the interconnection lines formed on the package board may be reduced to improve the signal integrity. As a result, the power consumption of the semiconductor device according to embodiments may be reduced, such that the semiconductor device may be easily applied to electronic devices.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor device comprising:
a package board having a front side and a back side opposite to each other;
a first memory device mounted on the front side of the package board and having data pins;
a second memory device mounted on the back side of the package board and having data pins of a same arrangement as the data pins of the first memory device; and
a controller configured to provide data signals to the first and second memory devices, a same one of the data signals provided from the controller to one data pin of the first memory device and one data pin of the second memory device, a distance between the one data pin of the first memory device and the one data pin of the second memory device shorter than respective distances between the one data pin of the first memory device and remaining ones of data pins of the second memory device.

2. The semiconductor device of claim 1, wherein the data pins of the first memory device are mirror-symmetric to the data pins of the second memory device.

3. The semiconductor device of claim 1, wherein the one data pin of the first memory device is connected to the one data pin of the second memory device through an inner interconnection disposed within the package board.

4. The semiconductor device of claim 1, wherein
each of the first and second memory devices includes first to 2ⁿ-th data pins (where the n is an integer); and
one of the data signals output from the controller is input into the one data pin of the first memory device and any one of the remaining data pins except the one data pin of the second memory device through a data line.

5. The semiconductor device of claim 1, wherein
the controller is configured to apply an on-die-termination (ODT) signal to the first and second memory devices, and
the controller is configured to disable the ODT signal when the data signals are transmitted to the first and second memory devices.

6. A semiconductor device comprising:
a first memory device having data pins;
a second memory device having data pins of a same arrangement as the data pins of the first memory device;
a controller configured to transmit data signals to the first and second memory devices; and
data lines connected between the controller and the first and second memory devices to transmit the data signals to the first and second memory devices in a swapped manner.

7. The semiconductor device of claim 6, wherein one of the data signals is input into one data pin of the first memory device and one data pin of the second memory device which have pin-addresses different from each other.

8. The semiconductor device of claim 7, wherein
each of the first and second memory devices includes first to 2ⁿ-th data pins (where the n is an integer), and
one of the data signals output from the controller is input into the one data pin of the first memory device and any one of remaining ones of the data pins of the second memory device through a data line.

9. The semiconductor device of claim 6, wherein
a same one of the data signals is provided to one data pin of the first memory device and one data pin of the second memory device from the controller; and
a distance between the one data pin of the first memory device and the one data pin of the second memory device is shorter than respective distances between the one data pin of the first memory device and remaining ones of the data pins of the second memory device.

10. The semiconductor device of claim 6, wherein
the controller is configured to provide an on-die-termination (ODT) signal to the first and second memory devices, and
the ODT signal is disabled when the data signals are transmitted to the first and second memory devices.

11. The semiconductor device of claim 6, wherein the controller is configured to provide a first chip selection signal and a second chip selection signal which control access to respective ones of the first memory device and the second memory device.

12. An apparatus, comprising:
a board;
a first memory device having a plurality of data pins;
a second memory device having a plurality of data pins; and
signal lines coupling the data pins of the first memory device to the data pins of the second memory device, the first and second memory devices coupled to opposing sides of the board in an overlapping relationship, one of the signal lines configured to carry same data to a first data pin of the first memory device and to a first data pin of the second memory device, the first data pin of the first memory device and the first data pin of the second memory device arranged at different pin positions.

13. The apparatus of claim 12, wherein the first and second memory devices are enabled by different chip select signals.

14. The apparatus of claim 12, wherein the first pin of the first memory device and the first pin of the second memory device have different pin addresses.

15. The apparatus of claim 12, wherein
the first data pin of the first memory device and the first data pin of the second memory device are separated by a first distance, and
the first data pin of the first memory device and remaining ones of the data pins of the second memory device are separated by distances greater than the first distance.

16. The apparatus of claim 12, wherein a center of the first memory device is offset from a center of the second memory device.

17. The apparatus of claim 12, wherein the signal lines are located within an interior of the board.

18. The apparatus of claim 12, further comprising:
a controller coupled the signal lines and the board.

19. The apparatus of claim 18, wherein
the controller has an on-die-termination (ODT) circuit, and
the controller is configured to disable the ODT circuit when said same data is carried by the one signal line for input into the first data pin of the first memory device and the first data pin of the second memory device.

20. The apparatus of claim 18, wherein the controller is coupled to the board at a location that does not overlap the first memory device or the second memory device.

21-34. (canceled)
